(19) United States
(12) Patent Application Publication
(10) Pub. No.: US 2026/0313830 A1
(43) Pub. Date: Oct. 8, 2026

(54) Liquid-Cooling Cabinet and Structural Layout Method Therefor, and Electronic Device

(71) Applicants: CHINA MOBILE GROUP DESIGN INSTITUTE CO., LTD., Beijing (CN); CHINA MOBILE COMMUNICATIONS GROUP CO., LTD., Beijing (CN)

(72) Inventors: Peng Gao, Beijing (CN); Jinfeng Li, Beijing (CN); Hailiang Luo, Beijing (CN); Hong Liu, Beijing (CN); Haibin Li, Beijing (CN); Yuguang Jiang, Beijing (CN); Lifeng Sun, Beijing (CN); Xuejun Wang, Beijing (CN); Lei Cheng, Beijing (CN); Yingbo Gao, Beijing (CN); Jinming Zhao, Beijing (CN); Zeqi Tian, Beijing (CN); Yunze Wang, Beijing (CN); Yuanyuan Wang, Beijing (CN); Bohua Chen, Beijing (CN)

(21) Appl. No.: 18/879,112

(22) PCT Filed: Feb. 8, 2024
(86) PCT No.: PCT/CN2024/076891

§ 371 Date: Dec. 26, 2024

(30) Foreign Application Priority Data
Apr. 21, 2023 (CN) 202310434001.6

(51) Int. Cl. H05K 7/20

(52) U.S. Cl. CPC H05K 7/20254; H05K 7/20772

(57) ABSTRACT

liquid-cooling cabinet and a structural layout method therefor. The liquid-cooling cabinet includes a cabinet frame and at least one connection module, which includes a transverse plate and at least one functional plate, wherein the transverse plate is provided with a plurality of transverse-plate connecting positions, and the functional plate is connected to any transverse-plate connecting position on the corresponding transverse plate, and a functional-plate interface is aligned with and in communication with a corresponding functional interface of a server in the cabinet frame; and/or the functional plate is perpendicularly provided with a plurality of functional-plate connecting positions, and the transverse plate is connected to any one of the functional-plate connecting positions, and the functional-plate interface is aligned with and in communication with the corresponding functional interface of the server in the cabinet frame. improving

### CROSS-REFERENCE TO RELATED APPLICATIONS

The present application is a national stage of PCT/CN2024/076891, filed on Feb. 8, 2024, which is based on and claims the priority to Chinese patent application No. 202310434001.6 filed on Apr. 21, 2023, the entire contents of which are incorporated herein by reference.

### FIELD

The present disclosure relates to the technical field of liquid-cooling cabinets, in particular to a liquid-cooling cabinet and a structural layout method therefor, and an electronic device.

### BACKGROUND

With the increasing national requirements for energy consumption index of the data center and the increasing power consumption of servers and chips, liquid cooling has a broader application prospect in the data center, and cold-plate liquid cooling is one of the main trending of liquid cooling technology.

Cold-plate liquid cooling takes away heat from the server by providing a cold plate to the main heating components of the server. Compared with the traditional air-cooling server, the cold-plate liquid-cooling server needs to be reformed to add a cold plate and reserve interfaces, etc. There are mainly three types of functional interfaces between cold-plate liquid-cooling server and liquid-cooling cabinet, namely, a liquid inlet interface and a liquid outlet interface for cooling, a power supply interface for power supply, and a communication interface for network connection; and the liquid inlet interface of liquid-cooling server is communicated with the liquid inlet interface of liquid-cooling cabinet through a quick connector, and the liquid outlet interface of liquid-cooling server is also communicated with the liquid outlet interface of liquid-cooling cabinet through a quick connector; the power supply interface of liquid-cooling server is communicated with the power supply interface of liquid-cooling cabinet through a power distribution socket or a copper bar, and the communication interface of the liquid-cooling server and the communication interface of the liquid-cooling cabinet are communicated through an optical fiber or a high-speed connector.

With regard to the structures of a liquid-cooling cabinet and a liquid-cooling server, because there is no unified standard for the liquid-cooling cabinet and the liquid-cooling server at present, the liquid-cooling cabinets of various manufacturers are incompatible with liquid-cooling servers of other manufacturers, mainly referring to the positions of the corresponding functional interfaces of the liquid-cooling cabinet and the liquid-cooling server do not correspond, resulting in that the corresponding functional interfaces cannot be aligned and connected, that is, a single liquid-cooling cabinet can only adapt to a specific type of liquid-cooling server, and when the liquid-cooling cabinet needs to be applied to other types of liquid-cooling servers, under the condition of unchanging the structure of the liquid-cooling cabinet, it is necessary to customize the liquid-cooling server, and under the condition that the structure of the liquid-cooling server remains unchanged, it is necessary to replace a new liquid-cooling cabinet that meets the requirements of alignment and connection, which will bring more obstacles to the present application of the liquid-cooling cabinet and the liquid-cooling server.

### SUMMARY

Embodiments of the present disclosure provides a liquid-cooling cabinet and a structural layout method therefor, which are used for solving the technical problems that the positions of the functional interface of the liquid-cooling cabinet of various manufacturers and the corresponding functional interface of the liquid-cooling server of other manufacturers are not corresponding, causing the functional interface of the liquid-cooling cabinet and the corresponding functional interface of the liquid-cooling server cannot be aligned and communicated, and the compatibilities of the liquid-cooling cabinets and the liquid-cooling servers is poor.

In a first aspect, embodiments of the present disclosure provide a liquid-cooling cabinet, including: a cabinet frame and at least one connection module; and the connection module comprises a transverse plate and at least one functional plate, and the functional plate is perpendicularly connected with the transverse plate, and the transverse plate is horizontally connected with a side face of the cabinet frame; the functional plate is provided with a plurality of functional-plate interfaces; the transverse plate is provided with a plurality of transverse-plate connecting positions, and the functional plate is connected to any transverse-plate connecting position on the corresponding transverse plate, and the functional-plate interface is aligned and in communication with a corresponding functional interface of a server in the cabinet frame; and/or the functional plate is perpendicularly provided with a plurality of functional-plate connecting positions, and the transverse plate is connected to any one of the functional-plate connecting positions, and the functional-plate interface is aligned and in communication with the corresponding functional interface of the server in the cabinet frame.

In a second aspect, embodiments of the present disclosure provide a structural layout method of a liquid-cooling cabinet for realizing the structure of the liquid-cooling cabinet according to embodiments of the first aspect of the present disclosure includes: determining the number of connection modules and the layout of functional plates in any one of the connection modules according to the type of the server; providing connection modules on any side face of the liquid-cooling cabinet according to the number and the layout; controlling the functional plate in the connection module to move horizontally and/or perpendicularly along the side face, and aligning and communicating the functional-plate interface on the functional plate with the corresponding functional interface of the server; wherein the server is the same type of server installed in the liquid-cooling cabinet area to which the corresponding connection module belongs.

In a third aspect, embodiments of the present disclosure provide an electronic device, including a processor and a memory storing a computer program, wherein when the processor executes the computer program, the steps of the structural layout method of the liquid-cooling cabinet according to embodiments of the second aspect of the present disclosure are realized.

The liquid-cooling cabinet provided in the present disclosure includes a cabinet frame and at least one connection module, and the connection module includes a transverse plate and at least one functional plate; the transverse plate is perpendicularly connected with the transverse plate; the transverse plate is horizontally connected to a side face of the cabinet frame; the functional plate is provided with a plurality of functional-plate interfaces; the transverse plate is provided with a plurality of transverse-plate connecting positions; the functional plate is connected to any transverse-plate connecting position on the corresponding transverse plate; and the functional-plate interface is aligned and communicated with the corresponding functional interface of the server in the cabinet frame; and/or, the functional plate is perpendicularly provided with a plurality of functional-plate connecting positions, and the transverse plate is connected to any functional-plate connecting position, and the functional-plate interface is aligned and communicated with the corresponding functional interface of the server in the cabinet frame. Because the functional plate is perpendicularly connected with the transverse plate, and the transverse plate is provided with a plurality of transverse-plate connecting positions, the functional plate is connected to any transverse-plate connecting position on the corresponding transverse plate, so that by controlling the functional plate, it is possible to adjust and replace the connected transverse-plate connecting position of the transverse plate, realize controlling the horizontal movement of the functional plate along the side face of the cabinet frame, thereby adjusting the position of the functional-plate interface relative to the corresponding functional interface of the server in the horizontal direction, aligning and communicating the functional-plate interface with the corresponding functional interface of the server; or, because the functional plate is perpendicularly connected with the transverse plate, the functional plate is perpendicularly provided with a plurality of functional-plate connecting positions, and the transverse plate is connected to any functional-plate connecting position, by controlling functional plate, the functional-plate connecting position connected with the transverse plate can be adjusted and replaced, the functional plate can be controlled to move perpendicularly along the side face of the cabinet frame, thereby adjusting the position of the functional-plate interface relative to the corresponding functional interface of the server in the perpendicular direction, aligning and communicating the functional-plate interface with the corresponding functional interface of the server; or, because functional plate is perpendicularly connected with the transverse plate, the transverse plate is provided with a plurality of transverse-plate connecting positions, the functional plate is perpendicularly provided with a plurality of functional-plate connecting positions, and the transverse plate and the functional plate are connected through the transverse-plate connecting position and the functional-plate connecting position, by controlling the functional plate, the functional-plate connecting position and the connected transverse-plate connecting position of the transverse plate can be adjusted and replaced and at the same time, the horizontal movement and the perpendicular movement of the functional plate along the side face of the cabinet frame can be controlled, so that the position of the functional-plate interface relative to the corresponding functional interface of the server can be adjusted in the horizontal direction and the perpendicular direction, and the functional-plate interface is aligned and communicated with the corresponding functional interface of the server. The above methods can make the positions of corresponding functional interfaces of different types of liquid-cooling cabinets and liquid-cooling servers correspond to each other, to improve the compatibilities of liquid-cooling cabinets and liquid-cooling servers.

### BRIEF DESCRIPTION OF THE DRAWINGS

In order to explain the technical solutions in the present disclosure or the related art more clearly, the drawings needed in descriptions of embodiments of the present disclosure or the prior art will be briefly introduced below. Obviously, the drawings in the following description are some embodiments of the present disclosure. For skills in the field, other drawings can be obtained according to these drawings without inventive work.

FIG. 1 is a first structural schematic diagram of a liquid-cooling cabinet provided by an embodiment of the present disclosure;

FIG. 2 is a second structural schematic diagram of a liquid-cooling cabinet provided by an embodiment of the present disclosure;

FIG. 3 is a third structural schematic diagram of a liquid-cooling cabinet provided by an embodiment of the present disclosure;

FIG. 4 is a fourth structural schematic diagram of the liquid-cooling cabinet provided by an embodiment of the present disclosure;

FIG. 5 is a fifth structural schematic diagram of the liquid-cooling cabinet provided by an embodiment of the present disclosure;

FIG. 6 is a sixth structural schematic diagram of the liquid-cooling cabinet provided by an embodiment of the present disclosure;

FIG. 7 is a seventh structural schematic diagram of the liquid-cooling cabinet provided by an embodiment of the present disclosure;

FIG. 8 is a detection circuit diagram in a liquid-cooling cabinet provided by an embodiment of the present disclosure;

FIG. 9 is first flow diagram of a structural layout method of a liquid-cooling cabinet provided by an embodiment of the present disclosure;

FIG. 10 is a second flow diagram of a structural layout method of a liquid-cooling cabinet provided by an embodiment of the present disclosure;

FIG. 11 is a schematic structural diagram of an electronic device provided by an embodiment of the present disclosure.

### DETAILED DESCRIPTION

In order to clearly describe the purpose, technical solution and advantages of the present disclosure, the technical solution in the present disclosure will be described clearly and completely with the drawings in embodiments of the present disclosure. Obviously, the described embodiments are part of embodiments of the present disclosure, but not all of them. Based on embodiments in the present disclosure, all other embodiments obtained by ordinary skills in the field without inventive work belong to the protection scope of the present disclosure.

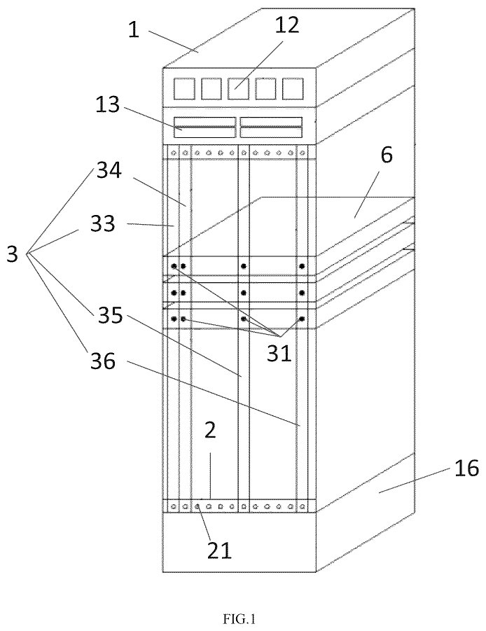

FIG. 1 is a first structural schematic diagram of a liquid-cooling cabinet provided by an embodiment of the present disclosure. Referring to FIG. 1, an embodiment of the present disclosure provides a liquid-cooling cabinet, which may include a cabinet frame 1 and at least one connection module.

The connection module comprises a transverse plate 2 and at least one functional plate 3, wherein the functional plate 3 is perpendicularly connected with the transverse plate 2, and the transverse plate 2 is horizontally connected with the side face of the cabinet frame 1.

The functional plate 3 is provided with a plurality of functional-plate interfaces 31.

The transverse plate 2 is provided with a plurality of transverse-plate connecting positions, and the functional plate 3 is connected to any transverse-plate connecting position on the corresponding transverse plate 2, and the functional-plate interface 31 is aligned and communicated with the corresponding functional interface of the server 6 in the cabinet frame 1; and/or the functional plate 3 is perpendicularly provided with a plurality of functional-plate connecting positions, and the transverse plate 2 is connected to any functional-plate connecting position, and the functional-plate interface 31 is aligned and communicated with the corresponding functional interface of the server 6 in the cabinet frame 1.

The functional plate 3 is perpendicularly connected with the transverse plate 2, and the transverse plate 2 is horizontally connected to the side face of the cabinet frame 1, that is, the functional plate 3 is perpendicularly connected with two transverse plates 2 in the same connection module, and these two transverse plates 2 are horizontally connected in parallel to the side face of the cabinet frame 1, and each functional plate 3 is used to communicate with the server 6 and provide corresponding function for the server 6.

The plurality of functional-plate interfaces 31 provided on the functional plate 3 can be provided horizontally or perpendicularly on the functional plate 3, or in any other arrangement mode, which is not limited here. In an embodiment, the plurality of functional-plate interfaces 31 are provided perpendicularly.

The transverse plate 2 is provided with a plurality of transverse-plate connecting positions, and the functional plate 3 is connected to any transverse-plate connecting position on the corresponding transverse plate 2, that is, by controlling the connection of the functional plate 3 with different transverse-plate connecting positions, the horizontal position of the functional plate 3 on the side face of the cabinet frame 1 can be changed, thereby adjusting the horizontal position of the functional-plate interface 31 relative to the corresponding functional interface of the server 6.

The functional plate 3 is perpendicularly provided with a plurality of functional-plate connecting positions, and the transverse plate 2 is connected to any functional-plate connecting position, that is, by controlling different functional-plate connecting positions to connect with the transverse plate 2, the perpendicular position of the functional plate 3 on the side face of the cabinet frame 1 can be changed, thereby adjusting the perpendicular position of the functional-plate interface 31 relative to the corresponding the functional interface of the server 6.

It is also possible to control the connection of different functional-plate connecting positions and different transverse-plate connecting positions, and at the same time change the horizontal and perpendicular positions of the functional plate 3 on the side face of the cabinet frame 1, so as to adjust the horizontal and perpendicular position of the functional-plate interface 31 relative to the corresponding functional interface of the server 6.

A functional pipeline or a functional circuit is provided in the functional plate 3. When a functional medium is input into the functional plate 3 or a functional module is connected with the functional plate 3, the functional medium can flow to the functional-plate interface 31 on the functional plate 3 through the functional pipeline in the functional plate 3, and then the functional medium is delivered to the server 6 through the corresponding functional interface of the server 6. The functional module can provide the corresponding function for the functional plate 3 through the functional circuit in the functional plate 3, and the functional plate 3 can provide the corresponding function for the server through the functional-plate interface 31 and the corresponding functional interface of the server 6.

The liquid-cooling cabinet provided in the present disclosure includes a cabinet frame and at least one connection module, and the connection module includes a transverse plate and at least one functional plate; the functional plate is perpendicularly connected with the transverse plate; the transverse plate is horizontally connected to a side face of the cabinet frame; the functional plate is provided with a plurality of functional-plate interfaces; the transverse plate is provided with a plurality of transverse-plate connecting positions; the functional plate is connected to any transverse-plate connecting position on the corresponding transverse plate; and the functional-plate interface is aligned and communicated with the corresponding functional interface of the server in the cabinet frame, and/or, the functional plate is perpendicularly provided with a plurality of functional-plate connecting positions, and the transverse plate is connected to any functional-plate connecting position, and the functional-plate interface is aligned and communicated with the corresponding functional interface of the server in the cabinet frame. Because the functional plate is perpendicularly connected with the transverse plate, and the transverse plate is provided with a plurality of transverse-plate connecting positions, the functional plate is connected to any transverse-plate connecting position on the corresponding transverse plate, by controlling the functional plate, it is possible to adjust and replace the connected transverse-plate connecting position of the transverse plate, realize controlling the horizontal movement of the functional plate along the side face of the cabinet frame, thereby adjusting the position of the functional-plate interface relative to the corresponding functional interface of the server in the horizontal direction, aligning and communicating the functional-plate interface with the corresponding functional interface of the server; or, because the functional plate is perpendicularly connected with the transverse plate, the functional plate is perpendicularly provided with a plurality of functional-plate connecting positions and the transverse plate is connected to any functional-plate connecting position, by controlling functional plate, the functional-plate connecting position connected with the transverse plate can be adjusted and replaced, the functional plate can be controlled to move perpendicularly along the side face of the cabinet frame, thereby adjusting the position of the functional-plate interface relative to the corresponding functional interface of the server in the perpendicular direction, aligning and communicating the functional-plate interface with the corresponding functional interface of the server; or, because the functional plate is perpendicularly connected with the transverse plate, the transverse plate is provided with a plurality of transverse-plate connecting positions, the functional plate is perpendicularly provided with a plurality of functional-plate connecting positions, and the transverse plate and the functional plate are connected through the transverse-plate connecting position and the functional-plate connecting position, by controlling the functional plate, the functional-plate connecting position and the connected transverse-plate connecting position of the transverse-plate can be adjusted and replaced and at the same time, the horizontal movement and the perpendicular movement of the functional plate along the side face of the cabinet frame can be controlled, so that the position of the functional-plate interface relative to the corresponding functional interface of the server can be adjusted in the horizontal direction and the perpendicular direction, and the functional-plate interface is aligned and communicated with the corresponding functional interface of the server. The above methods can make the positions of corresponding functional interfaces of different types of liquid-cooling cabinets and liquid-cooling servers correspond to each other, to improve the compatibilities of liquid-cooling cabinets and liquid-cooling servers.

Referring to FIG. 1, in an embodiment, the transverse-plate connecting position is the first positioning hole 21, and the functional plate 3 is connected to the corresponding first positioning hole 21.

In this embodiment, two transverse plates 2 in the same connection module are both provided with a plurality of first positioning holes 21, and both ends of the functional plate 3 are connected to the opposite first positioning holes 21 of the two transverse plates 2. If the functional-plate interface 31 on the functional plate 3 does not correspond to the corresponding functional interface of the server 6 at this time, by connecting the functional plate 3 to other opposite first positioning holes 21 of two transverse plates 2, so as to adjust the horizontal position of the functional-plate interface 31 on the functional plate 3 relative to the corresponding functional interface of the server 6, so that the position of the functional-plate interface 31 on the functional plate 3 corresponds to and is communicated with the position of the corresponding functional interface of the server 6.

Further, a redundant length can be designed for the functional plate 3. When adjusting the position of the functional plate 3, one end of the functional plate 3 can be kept fixed, and only the first positioning hole 21 connected with the other end of transverse plate 2 can be replaced, so that the functional plate 3 is tilted clockwise or counterclockwise. At this time, the horizontal position and perpendicular position of the functional-plate interface 31 on the functional plate 3 are changed, and the position adjustment of the corresponding functional interface of the server 6 can be realized in the horizontal and perpendicular directions, so that the position of the functional-plate interface 31 on the functional plate 3 can correspond to and communicate with the position of the corresponding functional interface of the server 6.

In this embodiment, the positioning holes are provided on the transverse plate, and by controlling the functional plate to connect with different positioning holes, the functional plate can move horizontally along the side face of the cabinet frame, so that the position of the functional-plate interface on the functional plate corresponds to and is communicated with the position of the corresponding functional interface of the server, and the compatibilities of the liquid-cooling cabinet and the liquid-cooling server is improved.

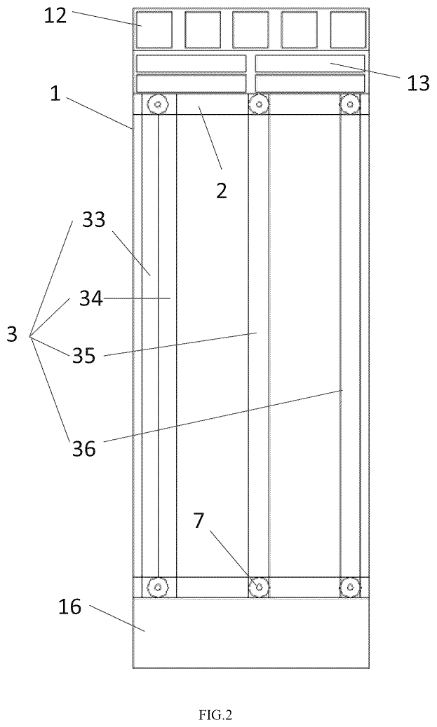

FIG. 2 is a second structural schematic diagram of a liquid-cooling cabinet provided by an embodiment of the present disclosure. Referring to FIGS. 1-2, in an embodiment, the transverse plate 2 is provided with a slide rail, and the functional plate 3 is suitable for moving along the slide rail, and the slide rail is provided with the plurality of transverse-plate connecting positions.

The slide rails can be provided at the opposite sides of two transverse plates 2 in any one connection module, and both ends of the functional plate 3 are connected with the slide rails of the corresponding transverse plates 2 in a sliding way.

In this embodiment, slide rails are provided at the opposite sides of two transverse plates 2 in a same connection module, and both ends of the functional plate 3 are respectively embedded in the slide rails of the two transverse plates 2, so that the functional plate 3 can slide along the slide rails and realize a horizontal movement along the side of the cabinet frame 1.

The functional plate 3 can slide along the slide rail by providing pulleys and sliders matched with the slide rail at both ends of the functional plate 3, or polishing both ends of the functional plate 3 to be smooth. In this embodiment, pulleys 7 matched with the slide rail are provided at both ends of the functional plate 3, so that the functional plate 3 can slide along the slide rail, thereby changing the transverse-plate connecting position connecting the functional plate 3 with the transverse plate 2, so as to adjust the horizontal position of the functional-plate interface 31 on the functional plate 3 relative to the corresponding functional interface of the server 6, so that the functional-plate interface 31 on the functional plate 3 corresponds to and is communicated with the corresponding functional interface of the server 6.

In addition, after the functional plate 3 moves to the preset position, the sliding part of the functional plate 3 can be locked by means of a buckle or the like to fix the functional plate 3.

In this embodiment, by providing the slide rail in the transverse plate and controlling the functional plate to slide in the slide rail, the functional plate moves horizontally along the side face of the cabinet frame, so that the functional-plate interface on the functional plate corresponds to and is communicated with the corresponding functional interface of the server, and the compatibilities of the liquid-cooling cabinet and the liquid-cooling server is improved.

FIG. 3 is a third structural schematic diagram of a liquid-cooling cabinet provided by an embodiment of the present disclosure. Referring to FIGS. 1 to 3, in an embodiment, the functional-plate connecting position is the second positioning hole 32, and the transverse plate 2 is connected to the corresponding second positioning hole 32.

In this embodiment, both ends of the functional plate 3 in the same connection module are provided with a plurality of second positioning holes 32, and the two transverse plates 2 are respectively connected to the second positioning holes 32 at both ends of the functional plate 3. If the functional-plate interface 31 on the functional plate 3 does not correspond to the corresponding functional interface of the server 6 at this time, by connecting the two transverse plates 2 to other second positioning holes 32 of the functional plate 3, the perpendicular position of the functional-plate interface 31 on the functional plate 3 relative to the corresponding functional interface of the server 6 can be adjusted, so that the functional-plate interface 31 on the functional plate 3 corresponds to and is communicated with the corresponding functional interface of the server 6.

In this embodiment, by providing the positioning holes on the functional plate, the transverse plate can be controlled to connected with different positioning holes, so that the functional plate moves perpendicularly along the side of the cabinet frame, so that the functional-plate interface on the functional plate corresponds to and is communicated with the corresponding functional interface of the server, and the compatibilities of the liquid-cooling cabinet and the liquid-cooling server is improved.

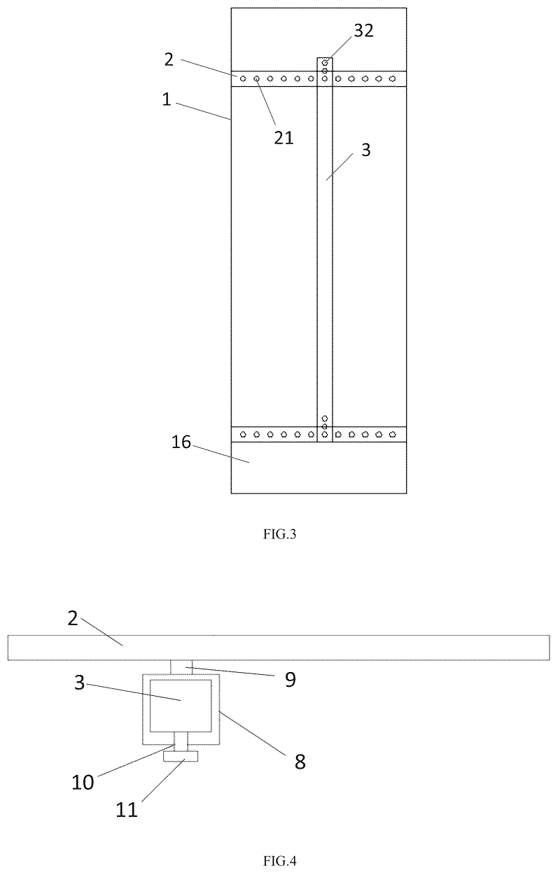

FIG. 4 is a fourth structural schematic diagram of a liquid-cooling cabinet provided by an embodiment of the present disclosure, and FIG. 4 is a top view relative to the perspective of FIG. 3; Referring to FIGS. 1-2 and 4, in an embodiment, the liquid-cooling cabinet may further include a fixing piece and a fixing bolt 11.

The fixing piece includes a fixing-piece frame 8 and a fixing-piece rear seat 9, and the fixing-piece rear seat 9 is connected between the fixing-piece frame 8 and the transverse plate 2.

The fixing-piece frame 8 is provided with a through hole 10, and the functional plate 3 penetrates through the fixing-piece frame 8 and is provided in the fixing-piece frame 8, and the fixing bolt 11 penetrates through the through hole 10 to press and fix the functional plate 3 and the fixing-piece frame 8, and the pressing portion of the functional plate 3 against the fixing-piece frame 8 is the functional-plate connecting position.

The length of the functional plate 3 is redundant relative to the perpendicular length between two transverse plates 2 in the same connection module, so as to avoid the situation that one end the of the functional plate 3 cannot be connected with the transverse plate 2 when moving perpendicularly. The fixing-piece frame 8 can be a hollow cube, a cylinder or other shapes, which is not limited here, as long as it can be sleeved on the functional plate 3. When the fixing bolt 11 is loosened, the functional plate 3 can be controlled to move perpendicularly in the fixing-piece frame 8. Then, the fixing-piece frame 8 and the functional plate 3 are pressed and fixed by using the fixing bolts 11, so that the perpendicular position of the functional-plate interface 31 on the functional plate 3 relative to the corresponding functional interface of the server 6 is changed, and therefore, the functional-plate interface 31 on the functional plate 3 corresponds to and is communicated with the position of corresponding functional interface of the server 6.

Further, when a plurality of first positioning holes 21 are horizontally provided on the transverse plate 2, the fixing-piece rear seat 9 can be designed as protrusions with sizes matching with the first positioning holes 21, so that the fixing-piece rear seat 9 can be embedded in different first positioning holes 21, and the functional plate 3 can be driven to move horizontally while fulfilling the perpendicular movement of the functional plate 3, realizing that the position of the functional-plate interface 31 on the functional plate 3 relative to the position of the corresponding functional interface of the server 6 can be accurately adjusted.

Further, when the transverse plates 2 are provided with sliding rails, the sliding rails can be provided on the sides of the two transverse plates 2 facing the functional plate 3. At this time, the fixing-piece rear seat 9 can be designed as a pulley, a slider, or a polished protrusion, so that the fixing-piece rear seat 9 can be embedded in the sliding rails to slide horizontally, and the functional plate 3 can be driven to move horizontally while fulfilling the perpendicular movement of the functional plate 3, so as to realize that the position of the functional-plate interface 31 on the functional plate 3 relative to the position of the corresponding functional interface of the server 6 can be accurately adjusted.

In this embodiment, by providing the fixing piece and the fixing bolt, on the one hand, the fixing-piece frame can be connected with the functional plate through the fixing bolt, and on the other hand, the fixing-piece frame can be connected with the transverse plate through the fixing-piece rear seat, so that the transverse plate can be connected with the functional plate. When the perpendicular position of the functional-plate interface on the functional plate needs to be adjusted, the fixing bolt can be loosened to control the functional plate to move perpendicularly to a preset position in the fixing-piece frame, and then the fixing bolt can be screwed into the through hole to press and fix the functional plate and the fixing frame to realize the perpendicular movement of the functional plate along the side face of the cabinet frame, so as to make the functional-plate interface on the functional plate correspond to and communicate with the corresponding functional interface of the server, thus improving the compatibilities of the liquid-cooling cabinet and the liquid-cooling server.

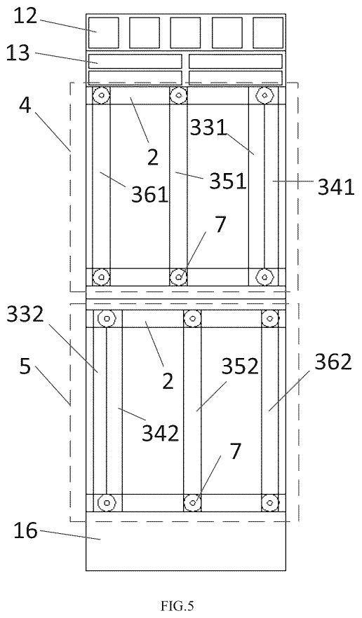

FIG. 5 is a fifth structural schematic diagram of a liquid-cooling cabinet provided by an embodiment of the present disclosure; Referring to FIGS. 1-5 , in an embodiment, functional plates with the same function in any two connection modules are interconnected, and the layout of functional plates in at least one connection module is different from the layout of functional plates in other connection modules.

The functional plate 3 may be a liquid inlet main plate 33, a liquid outlet main plate 34, a power main plate 35 or a communication main plate 36, or other functional main plates, which is not limited here. The functional plates with the same function in any two connection modules are interconnected, that is, the liquid inlet main plate 33 in all connection modules are interconnected, the liquid outlet main plates 34 in all connection modules are interconnected, the power main plates 35 in all connection modules are interconnected and the communication main plates 36 in all connection modules are interconnected, so as to facilitate unified control of various types of functional plates in all modules.

Different layouts include different numbers, different types, different arrangement order of functional plates 3, or other differences, which are not limited here. Because the number, type or arrangement order of functional interfaces may be different while applied to different types of servers 6, a plurality of connection modules can be provided on the side of the cabinet frame 1, and each connection module corresponds to one type of server 6.

For example, in FIG. 5, two connection modules are provided to correspond to two types of servers respectively. The liquid-cooling cabinet area to which the first connection module 4 belongs is used to install the first type of server, and the liquid-cooling cabinet area to which the second connection module 5 belongs is used to install the second type of server. The functional interfaces on the back of the first type of server can be a communication interface, a power interface, a liquid inlet interface and a liquid outlet interface in turn from left to right, then the first communication main plate 361, the first power main plate 351, the first liquid inlet main plate 331 and the first liquid outlet main plate 341 need to be correspondingly provided in the first connection module 4 from left to right, and these main plates are slidably connected with the transverse plate 2 in the first connection module 4 through sliding rails, so as to adjust the horizontal position of the functional-plate interface on the main plate relative to the corresponding functional interface of the server through horizontal movement, so that the interface of the communication main plate on the first communication main plate 361 is aligned with the corresponding communication interface of the server, the interface of the power main plate on the first power main plate 351 is aligned with the corresponding power interface of the server, the interface of the liquid inlet main plate on the first liquid inlet main plate 331 is aligned with the corresponding liquid inlet interface of the server, and the interface of the liquid outlet main plate on the first liquid outlet main plate 341 is aligned with the corresponding liquid outlet interface of the server. When there is more than one server installed in the first connection module 4, there are also a plurality of functional-plate interfaces on each functional plate, so that by controlling the horizontal movement of the functional plates, the one-to-one alignment of the functional-plate interfaces with the corresponding functional interfaces of multiple servers can be achieved.

Similarly, the functional interfaces on the back of the second type of server can be a liquid inlet interface, a liquid outlet interface, a power supply interface and a communication interface in turn from left to right, so the second liquid inlet main plate 332, the second liquid outlet main plate 342, the second power main plate 352 and the second communication main plate 362 need to be correspondingly provided in the second connection module 5 from left to right, and these main plates are connected with the transverse plate 2 in the second connection module 5 in a sliding way through sliding rails, so as to adjust the horizontal position of the functional-plate interface on the main plate relative to the corresponding functional interface of the server through horizontal movement, so that the interface of the liquid inlet main plate on the second liquid inlet main plate 332 is aligned with the corresponding liquid inlet interface of the server, the interface of the liquid outlet main plate on the second liquid outlet main plate 342 is aligned with the corresponding liquid outlet interface of the server, the interface of the power main plate on the second power main plate 352 is aligned with the corresponding power supply interface of the server, and the interface of the communication main plate on the second communication main plate 362 is aligned with the corresponding communication interface of the server. When there is more than one server installed in the second connection module 5, there are also a plurality of functional-plate interfaces on each functional plate, so that by controlling the horizontal movement of the functional plates, the one-to-one alignment of the functional-plate interfaces with the corresponding functional interfaces of multiple servers can be achieved.

In addition, the first liquid inlet main plate 331 and the second liquid inlet main plate 332 communicate with each other, the first liquid outlet main plate 341 and the second liquid outlet main plate 342 communicate with each other, the first power main plate 351 and the second power main plate 352 communicate with each other, and the first communication main plate 361 and the second communication main plate 362 communicate with each other. The corresponding main plates can communicate with each other through pipes, cables, cables, hoses, flexible wires or other means, which is not limited here.

Through the above arrangement, different types of liquid-cooling servers can be installed in the first connection module 4 and the second connection module 5, and the two types of liquid-cooling servers can be uniformly controlled through the interconnected functional plates.

Further, a liquid-cooling server can be installed in the first connection module 4, and all functional plates in the second connection module 5 can be removed at the same time, and an air-cooling server can be installed in the removed second connection module 5, so that the liquid-cooling server and the air-cooling server can be installed in the same cabinet at the same time.

By dividing the connection modules, the present embodiment can adjust the required functional plate layout for each connection module, thus realizing the arrangement of liquid-cooling servers with different interface positions on the same cabinet, enhancing the flexibility of the liquid-cooling cabinet, and also realizing the simultaneous deployment of the liquid-cooling server and the air-cooling server in the same cabinet, further improving the compatibilities of the liquid-cooling cabinet and the server.

FIG. 6 is a sixth structural schematic diagram of a liquid-cooling cabinet provided by an embodiment of the present disclosure.

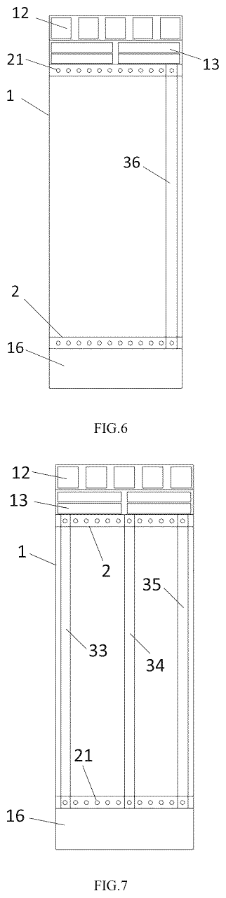

FIG. 7 is a seventh structural schematic diagram of a liquid-cooling cabinet provided by an embodiment of the present disclosure.

Referring to FIGS. 1-7, in an embodiment, the number of functional plates 3 in each connection module can be set according to actual requirements.

The connection module in FIG. 6 only includes a communication main plate 36, and the connection module in FIG. 7 includes a liquid inlet main plate 33, a liquid outlet main plate 34 and a power main plate 35, and the distance between the liquid inlet main plate 33 and the liquid outlet main plate 34 is increased.

Further, the liquid-cooling cabinet also includes a power module 12 and a switch module 13.

The power module 12 is connected with the power main plate 35, so that the power module 12 supplies power to the server 6 through the interface of power main plate and the corresponding functional interface of the server 6 in the cabinet frame 1, wherein the interface of power main plate and the corresponding functional interface of the server 6 are aligned with each other.

The switch module 13 is connected with the communication main plate 36, so that the switch module 13 communicates with the server 6 through the interface of the communication main plate and the corresponding functional interface of the server 6 in the cabinet frame 1, wherein the interface of the communication main plate and the corresponding functional interface of the server 6 are aligned with each other.

The positions of the power module 12 and the switch module 13 can be set according to actual requirements, which can be set at the top of the cabinet, or can be set between any two connection modules when there are a plurality of connection modules.

It is also possible to set a liquid inlet at the bottom of the liquid inlet main plate 33, a liquid outlet at the bottom of the liquid outlet main plate 34, and a reserved space 16 at the bottom of the liquid-cooling cabinet. The liquid inlet and the liquid outlet are used to connect with a heat exchange unit, and the heat exchange unit can be a centralized heat exchange unit provided outside the liquid-cooling cabinet or a distributed heat exchange unit integrated in the reserved space 16 in the cabinet. The power main plate 35 can be connected with the power module 12 through cables, and the power main plate 35 has power supply capability after their connection; and the communication main plate 36 can be connected with the switch module 13 through network cables, and the communication main plate 36 has network communication capability after their connection.

Referring to FIG. 1, the liquid-cooling cabinet is used for carrying cold-plate liquid-cooling servers and cooling, supplying power and communicating with the servers 6. The servers 6 are inserted into the cabinet for installation from the front side of the cabinet, and at the rear side of the cabinet, various functional interfaces on the servers 6 are connected with corresponding functional-plate interfaces 31.

After the server 6 is installed on and communicated with the cabinet, the cabinet cools the server 6 through the interface of the liquid inlet main plate and the interface of the liquid outlet main plate. The circulation of the cooling working medium is as follows: the low-temperature cooling working medium from the heat exchange unit enters the liquid inlet main plate 33 through the liquid inlet at the bottom of the liquid inlet main plate 33, and then enters the internal cooling plate of the server 6 through the interface of the liquid inlet main plate and the liquid inlet interface of the server 6 to cool the heating components, and after absorbing the heat of the server 6, the cooling working medium becomes a high-temperature working medium, and enters liquid outlet main plate 34 through the liquid outlet interface of the server 6 and the interface of the liquid outlet main plate, and returns to the heat exchange unit for a next circulation.

In these embodiment, the number and types of functional plates in the connection module are flexibly set, and the power module and switch module in the cabinet are flexibly set, so that the cooling, communication and power supply requirements of different types of servers can be met, and the compatibilities of the liquid-cooling cabinet and the server can be improved.

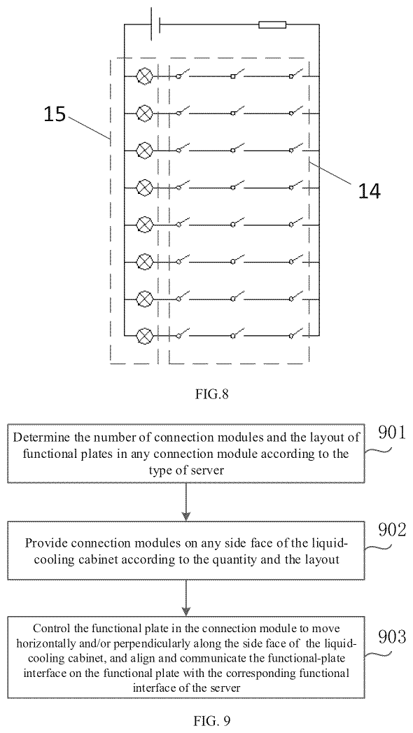

FIG. 8 is a detection circuit diagram in a liquid-cooling cabinet provided by an embodiment of the present disclosure; Referring to FIGS. 1-8 , in an embodiment, the liquid-cooling cabinet may further include a detection switch 14.

The detection switch 14 is provided at the functional-plate interface 31. Through the functional-plate interface 31 and the corresponding functional interface of the server 6 in the cabinet frame 1, the detection switch 14 forms a series loop with an indicator light 15 on the server 6 for determining whether each functional-plate interface 31 is connected with the corresponding functional interface of the server 6.

In FIG. 8, each indicator light 15 is connected in series with three detection switches 14, and then connected in series with a power supply and a resistor to form a detection loop. Each detection loop corresponds to one server 6, that is, in FIG. 8, there are eight servers 6, and each server 6 includes three functional interfaces, so there are three different types of functional-plate interfaces 31 corresponding to each server 6, and the three detection switches 14 in each detection loop are provided at these three different types of functional-plate interfaces 31. When the three detection switches 14 are closed and the indicator light 15 on the corresponding server 6 is on, it is determined that the three functional-plate interfaces 31 are connected with the functional interfaces of the corresponding server 6, that is, the server 6 is installed correctly; and if the indicator light on the server 6 is off, it is determined that at least one functional-plate interface 31 is not connected with the functional interface of the corresponding server 6, that is, the server 6 is not installed correctly.

In addition, because each detection loop is connected in parallel, the detection loops will not interfere with each other, thus not affecting the accuracy of detection.

It should be noted that if it is only necessary to detect whether a certain functional-plate interface 31 is connected with the functional interface of the corresponding server 6, the detection switch 14 can be only provided on this one functional-plate interface 31, and then the detection switch 14 is connected in series with the indicator light 15, the power supply and the resistor. In addition, if it is necessary to accurately determine which functional-plate interface 31 is not connected with the functional interface of the corresponding server 6 when the indicator light 15 is off, a plurality of detection switches 14 corresponding to the same server 6 can be connected in parallel and then connected in series with the indicator light 15, the power supply and the resistor.

In this embodiment, by setting the detection switch and the detection circuit, it is possible to detect whether each functional-plate interface is connected with the corresponding functional interface of the server, so as to determine whether the server is installed correctly.

FIG. 9 is one of the flow charts of the structural layout method of the liquid-cooling cabinet provided by embodiments of the present disclosure. Referring to FIG. 9, an embodiment of the present disclosure provides a structural layout method of a liquid-cooling cabinet, which is used to realize the aforementioned structure of the liquid-cooling cabinet, and may include:

901. The number of connection modules and the layout of functional plates in any connection module is determine according to the type of server;

902. Connection modules is provided on any side face of the liquid-cooling cabinet according to the quantity and the layout;

903. The functional plate in the connection module is controlled to move horizontally and/or perpendicularly along the side face of the liquid-cooling cabinet, and the functional-plate interface on the functional plate is aligned and communicated with the corresponding functional interface of the server.

The server is of the same type installed in the liquid-cooling cabinet area to which the corresponding connection module belongs.

In step 901, positions, types and numbers of functional interfaces of server may be different in different types of servers, so the number of connection modules and the layout of functional plates in any connection module can be determined according to the types of servers. For example, there are two types of servers, the first type of server has three interfaces on the back face, namely, an interface A, an interface B and an interface C from left to right, and the second type of server has four interfaces on the back face, namely, from left to right, there are an interface B, an interface A, an interface D and an interface C in turn, so it can be determined that two connection modules are needed. These two connection modules divide the liquid-cooling cabinet into two areas. The area where the first connection module belongs is used to install the first type of server, and the area where the second connection module belongs is used to install the second type of server. The first connection module needs to be equipped with a functional plate A, a functional plate B and a functional plate from C left to right, and the second connection module needs to be equipped with a functional plate B, a functional plate A, a functional plate D and a functional plate C from left to right.

Further, the functional plate an in the first connection module and the functional plate an in the second connection module can communicate with each other, the functional plate B in the first connection module and the functional plate B in the second connection module can communicate with each other, and the functional plate C in the first connection module and the functional plate C in the second connection module can communicate with each other.

In step 902, connection modules can be provided on the back face of the cabinet frame according to the number and the layout determined in step 901.

In step 903, the first type server can be installed in the liquid-cooling cabinet area to which the first connection module belongs, and the second type server can be installed in the liquid-cooling cabinet area to which the second connection module belongs, and the functional plates A, B and C in the first connection module can be controlled to move horizontally and/or perpendicularly, so as to adjust the horizontal positions of the functional-plate interfaces of the functional plates A, B and C relative to the interfaces A, B and C of the corresponding server, so that the functional-plate interface on the functional plate A is aligned and communicated with the interface A of the corresponding server, the functional-plate interface on the functional plate B is aligned and communicated with the interface B of the corresponding server, and the functional-plate interface on the functional plate C is aligned and communicated with the interface C of the corresponding server. The control method for the functional plate in the second connection module is the same.

In these embodiments, connection modules and functional plates in the connection modules are provided on the back face of the liquid-cooling cabinet according to the types of servers, so that the layout of the functional plates in each module is the similar to the layout of each interface of the corresponding type of server. Then, by controlling the functional plates to move horizontally and/or perpendicularly along the back face of the liquid-cooling cabinet, the functional-plate interfaces on the functional plates are aligned and communicated with the corresponding functional interfaces of the server, thus improving the compatibilities of the liquid-cooling cabinet and the server.

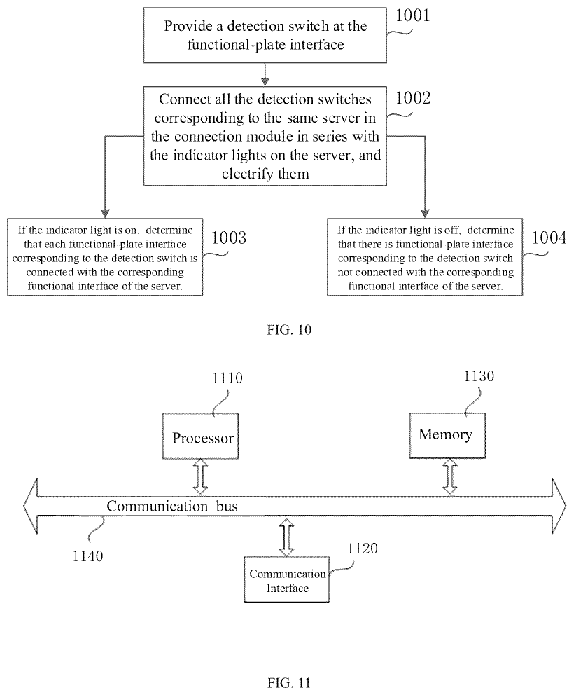

FIG. 10 is a second flow diagram of the structural layout method of liquid-cooling cabinet provided by an embodiment of the present disclosure. Referring to FIGS. 8 and 10, in an embodiment, after aligning and communicating the functional-plate interface on the functional plate with the corresponding functional interface of the server, the method may include:

1001. A detection switch is provided at the functional-plate interface;

1002. All the detection switches in the connection module corresponding to the same server are connected in series with the indicator lights on the server, and are electrified.

1003. If the indicator light is on, it is determined that each functional-plate interface corresponding to the detection switch is connected with the corresponding functional interface of the server.

1004. If the indicator light is off, it is determined that there is functional-plate interface corresponding to the detection switch not connected with the corresponding functional interface of the server.

In step 1001, a detection switch may be set at one or more functional-plate interfaces to be detected, which is not limited here.

In step 1002, one or more detection switches corresponding to the same server are connected in series with the indicator light, and are electrified and communicated, wherein a plurality of detection switches can be connected in series in turn and then connected in series with the indicator light; at this time, among the functional-plate interfaces corresponding to the detection switches, if any functional-plate interface is not connected with the corresponding functional interface of the server, the indicator light is off; Then a plurality of detection switches can also be connected in parallel and then connected in series with the indicator light. At this time, if the indicator light is not off, the fact that which functional-plate interface has a connection fault with the corresponding functional interface of the server can be quickly located.

From step 1003 to step 1004, in this example, a plurality of detection switches are sequentially connected in series and then connected in series with the indicator light. Therefore, when the indicator light is on, it means that all the functional interfaces of the corresponding server are connected with the functional-plate interfaces, that is, the server is installed correctly; and when the indicator light is off, it means that at least one functional interface of the corresponding server is not connected with the functional-plate interfaces, that is, the server is not installed correctly.

These embodiments can detect whether each functional interface of the server is connected with the corresponding functional-plate interface by setting the detection switch and the detection circuit, so as to determine whether the server is installed correctly.

FIG. 11 illustrates a physical structure of an electronic device. As shown in FIG. 11, the electronic device may include a processor 1110, a communication interface 1120, a memory 1130 and a communication bus 1140, wherein the processor 1110, the communication interface 1120 and the memory 1130 communicate with each other through the communication bus 1140. The processor 1110 can call the computer program in the memory 1130 to execute the steps of the structural layout method of the liquid-cooling cabinet, including, for example:
determining the number of connection modules and the layout of functional plates in any one of the connection modules according to the type of the server;
providing connection modules on any side face of the liquid-cooling cabinet according to the number and the layout;
controlling the functional plate in the connection module to move horizontally and/or perpendicularly along the side face, and aligning and communicating the functional-plate interface on the functional plate with the corresponding functional interface of the server; The servers are the same type servers installed in the liquid-cooling cabinet area to which the corresponding connection module belongs.

In addition, the logical instruction in the above-mentioned memory 1130 can be realized in the form of software functional unit, and can be stored in a computer-readable storage medium when it is sold or used as an independent product. Based on such understanding, the essential technical solution of the present disclosure, or a part that contributes to the related art of the present disclosure or a part of the technical solution of the present disclosure can be embodied in the form of a software product, and the computer software product is stored in a storage medium and includes several instructions to make a computer device (which can be a personal computer, a server, a network device, etc.) execute all or part of the steps of the method described in various embodiments of the present disclosure. The aforementioned storage medium include: a U disk, a mobile hard disk, a read-only memory (ROM), a random-access memory (RAM), a magnetic disk or an optical disk and other medium that can store program codes.

On the other hand, embodiments of the present disclosure also provide a computer program product, and the computer program product includes a computer program, which can be stored on a non-transient computer-readable storage medium, and when the computer program is executed by a processor, the computer can execute the steps of the structural layout method of the liquid-cooling cabinet provided in the above embodiments, including, for example:
determining the number of connection modules and the layout of functional plates in any one of the connection modules according to the type of the server;
providing connection modules on any side face of the liquid-cooling cabinet according to the number and the layout;
controlling the functional plate in the connection module to move horizontally and/or perpendicularly along the side face of the liquid-cooling cabinet, and aligning and communicating the functional-plate interface on the functional plate with the corresponding functional interface of the server; The servers are the same type servers installed in the liquid-cooling cabinet area to which the corresponding connection module belongs.

On the other hand, embodiments of the present disclosure also provide a processor-readable storage medium, and a computer program is stored in the processor-readable storage medium, and the computer program is used for making the processor to execute the steps of the methods provided in the above embodiments, for example, including:
determining the number of connection modules and the layout of functional plates in any one of the connection modules according to the type of the server;
providing connection modules on any side face of the liquid-cooling cabinet according to the number and the layout;
controlling the functional plate in the connection module to move horizontally and/or perpendicularly along the side face of the liquid-cooling cabinet, and aligning and communicating the functional-plate interface on the functional plate with the corresponding functional interface of the server; The servers are the same type servers installed in the liquid-cooling cabinet area to which the corresponding connection module belongs.

The processor-readable storage medium can be any available medium or data storage device that the processor can access, including but not limited to a magnetic memory (such as a floppy disk, a hard disk, a magnetic tape, a magneto-optical disk (MO), etc.), an optical memory (such as a CD, a DVD, a BD, a HVD, etc.), and a semiconductor memory (such as a ROM, a EPROM, a EEPROM, a non-volatile memory (NAND FLASH), a solid state disk (SSD).

From the description of the above embodiments, those skills in the art can clearly understand that each embodiment can be realized by means of a software and a necessary general hardware platform, and it can also be realized by a hardware. Based on such understanding, the essence of the above technical solution or the part that has contributed to the related art can be embodied in the form of a software product, and the computer software product can be stored in a computer-readable storage medium, such as a ROM/RAM, a magnetic disk, an optical disk, etc., and includes several instructions for making a computer device (which can be a personal computer, a server, or a network device, etc.) execute the methods described in various embodiments or some parts of embodiments.

In a first aspect, embodiments of the present disclosure provide a liquid-cooling cabinet, including: a cabinet frame and at least one connection module; and the connection module comprises a transverse plate and at least one functional plate, and the functional plate is perpendicularly connected with the transverse plate, and the transverse plate is horizontally connected with a side face of the cabinet frame; the functional plate is provided with a plurality of functional-plate interfaces; the transverse plate is provided with a plurality of transverse-plate connecting positions, and the functional plate is connected to any transverse-plate connecting position on the corresponding transverse plate, and the functional-plate interface is aligned and in communication with a corresponding functional interface of a server in the cabinet frame; and/or the functional plate is perpendicularly provided with a plurality of functional-plate connecting positions, and the transverse plate is connected to any one of the functional-plate connecting positions, and the functional-plate interface is aligned and in communication with the corresponding functional interface of the server in the cabinet frame.

In an embodiment, the transverse-plate connecting position is a first positioning hole, and the functional plate is connected to the corresponding first positioning hole.

In an embodiment, the transverse plate is provided with a slide rail, and the functional plate is suitable for moving along the slide rail, and the plurality of transverse-plate connecting positions is provided on the slide rail.

In an embodiment, the functional-plate connecting position is a second positioning hole, and the transverse plate is connected to the corresponding second positioning hole.

In an embodiment, the liquid-cooling cabinet further includes a fixing piece and a fixing bolt; the fixing piece comprises a fixing-piece frame and a fixing-piece rear seat, and the fixing-piece rear seat is connected between the fixing-piece frame and the transverse plate; the fixing-piece frame is provided with a through hole, the functional plate penetrates through the fixing-piece frame and is provided in the fixing-piece frame, and the fixing bolt penetrates through the through hole to tightly connect the functional plate with the fixing-piece frame, and a pressing portion between the functional plate and the fixing-piece frame is the functional-plate connecting position.

In an embodiment, the functional plates with the same function in any two connection modules are interconnected, and the layout of functional plate in at least one connection module is different from the layout of functional plate in other connection modules.

In an embodiment, the functional plate includes one of a liquid inlet main plate, a liquid outlet main plate, a power main plate or a communication main plate.

In an embodiment, the liquid-cooling cabinet further includes a power module; the power module is connected with the power main plate, so that the power module supplies power to the server through the interface of the power main plate and the corresponding functional interface of the server in the cabinet frame, wherein the interface of the power main plate and the corresponding functional interface of the server in the cabinet frame are aligned with each other.

In an embodiment, the liquid-cooling cabinet further includes a switch module; the switch module is connected with the communication main plate, so that the switch module communicates with the server through the interface of the communication main plate and the corresponding functional interface of the server in the cabinet frame, wherein the interface of the communication main plate and the corresponding functional interface of the server in the cabinet frame are aligned with each other.

In an embodiment, the liquid-cooling cabinet further includes a detection switch; the detection switch is provided at the functional-plate interface, and forms a series loop with an indicator light on the server through the functional-plate interface and the corresponding functional interface of the server in the cabinet frame, and is configured to determine whether each functional-plate interface is communicated with the corresponding functional interface of the server.

In a second aspect, embodiments of the present disclosure provide a structural layout method of a liquid-cooling cabinet for realizing the structure of the liquid-cooling cabinet according to embodiments of the first aspect of the present disclosure includes: determining the number of connection modules and the layout of functional plates in any one of the connection modules according to the type of the server; providing connection modules on any side face of the liquid-cooling cabinet according to the number and the layout; controlling the functional plate in the connection module to move horizontally and/or perpendicularly along the side face, and aligning and communicating the functional-plate interface on the functional plate with the corresponding functional interface of the server; wherein the server is the same type of server installed in the liquid-cooling cabinet area to which the corresponding connection module belongs.

In an embodiment, after aligning and communicating the functional-plate interface on the functional plate with the corresponding functional interface of the server, the method includes providing a detection switch at the functional-plate interface; connecting all the detection switches corresponding to the same server in the connection module in series with an indicator light on the server, and electrifying and communicating them; under the condition that the indicator light is on, determining that each functional-plate interface corresponding to the detection switch is in communication with the corresponding functional interface of the server; under the condition that the indicator light is off, determining that there is functional-plate interface corresponding to the detection switch not in communication with the corresponding functional interface of the server.

In a third aspect, embodiments of the present disclosure provide an electronic device, including a processor and a memory storing a computer program, wherein when the processor executes the computer program, the steps of the structural layout method of the liquid-cooling cabinet according to embodiments of the second aspect of the present disclosure are realized.

In a fourth aspect, embodiments of the present disclosure provide a non-transient computer-readable storage medium, including a computer program, when the computer program is executed by a processor, the steps of the structural layout method of the liquid-cooling cabinet according to embodiments of the second aspect of the present disclosure are realized.

Finally, it should be explained that the above embodiments are only used to illustrate the technical solution of the present disclosure, but not to limit it. Although the present disclosure has been described in detail with reference to the foregoing embodiments, it should be understood by those skills in the art that they can still modify the technical solutions described in the foregoing embodiments or replace some technical features with equivalents; However, these modifications or substitutions do not make the essence of the corresponding technical solutions deviate from the spirit and scope of the technical solutions of various embodiments of the present disclosure.

1. A liquid-cooling cabinet, comprising: a cabinet frame and at least one connection module;
wherein the connection module comprises a transverse plate and at least one functional plate, and the functional plate is perpendicularly connected with the transverse plate, and the transverse plate is horizontally connected with a side face of the cabinet frame;
the functional plate is provided with a plurality of functional-plate interfaces;
the transverse plate is provided with a plurality of transverse-plate connecting positions, and the functional plate is connected to any transverse-plate connecting position on the corresponding transverse plate, and the functional-plate interfaces are aligned and in communication with corresponding functional interfaces of a server in the cabinet frame; and/or
the functional plate is perpendicularly provided with a plurality of functional-plate connecting positions, and the transverse plate is connected to any one of the functional-plate connecting positions, and the functional-plate interfaces are aligned and in communication with the corresponding functional interfaces of the server in the cabinet frame.

2. The liquid-cooling cabinet according to claim 1, wherein,
the transverse-plate connecting position is a first positioning hole, and the functional plate is connected to the corresponding first positioning hole.

3. The liquid-cooling cabinet according to claim 1, wherein,
the transverse plate is provided with a slide rail, and the functional plate is suitable for moving along the slide rail, and the plurality of transverse-plate connecting positions is provided on the slide rail.

4. The liquid-cooling cabinet according to claim 1, wherein,
the functional-plate connecting position is a second positioning hole, and the transverse plate is connected to the corresponding second positioning hole.

5. The liquid-cooling cabinet according to claim 1, further comprising: a fixing piece and a fixing bolt;
the fixing piece comprises a fixing-piece frame and a fixing-piece rear seat, and the fixing-piece rear seat is connected between the fixing-piece frame and the transverse plate;
the fixing-piece frame is provided with a through hole, the functional plate penetrates through the fixing-piece frame and is provided in the fixing-piece frame, and the fixing bolt penetrates through the through hole to press and connect the functional plate with the fixing-piece frame, and a pressing portion on the functional plate against the fixing-piece frame is the functional-plate connecting position.

6. The liquid-cooling cabinet according to claim 1, wherein,
the functional plates with the same function in any two connection modules are interconnected, and the layout of functional plates in at least one connection module is different from the layout of functional plates in other connection modules.

7. The liquid-cooling cabinet according to claim 1, wherein,
the functional plate comprises at least one of a liquid inlet main plate, a liquid outlet main plate, a power main plate or a communication main plate.

8. The liquid-cooling cabinet according to claim 7, further comprising: a power module;
the power module is connected with the power main plate, so that the power module supplies power to the server through the interface of the power main plate and the corresponding functional interface of the server in the cabinet frame, wherein the interface of power main plate and the corresponding functional interface of the server in the cabinet frame are aligned with each other.

9. The liquid-cooling cabinet according to claim 7, further comprising: a switch module;
the switch module is connected with the communication main plate, so that the switch module communicates with the server through the interface of the communication main plate and the corresponding functional interface of the server in the cabinet frame, wherein the interface of the communication main plate and the corresponding functional interface of the server in the cabinet frame are aligned with each other.

10. The liquid-cooling cabinet according to claim 1, further comprising: a detection switch;
the detection switch is provided at the functional-plate interface, and forms a series loop with an indicator light on the server through the functional-plate interface and the corresponding functional interface of the server in the cabinet frame, and is configured to determine whether the functional-plate interfaces are communicated with the corresponding functional interfaces of the server.

11. A structural layout method of a liquid-cooling cabinet, for realizing the structure of the liquid-cooling cabinet, wherein the liquid-cooling cabinet comprising: a cabinet frame and at least one connection module; wherein the connection module comprises a transverse plate and at least one functional plate, and the functional plate is perpendicularly connected with the transverse plate, and the transverse plate is horizontally connected with a side face of the cabinet frame; the functional plate is provided with a plurality of functional-plate interfaces; the transverse plate is provided with a plurality of transverse-plate connecting positions, and the functional plate is connected to any transverse-plate connecting position on the corresponding transverse plate, and the functional-plate interfaces are aligned and in communication with corresponding functional interfaces of a server in the cabinet frame; and/or the functional plate is perpendicularly provided with a plurality of functional-plate connecting positions, and the transverse plate is connected to any one of the functional-plate connecting positions, and the functional-plate interfaces are aligned and in communication with the corresponding functional interfaces of the server in the cabinet frame,
the method comprising:
determining the number of connection modules and the layout of functional plates in any one of the connection modules according to the type of the server;
providing connection modules on any side face of the liquid-cooling cabinet according to the number and the layout;
controlling the functional plate in the connection module to move horizontally and/or perpendicularly along the side face, and aligning and communicating the functional-plate interfaces on the functional plate with the corresponding functional interfaces of the server;
wherein the server is the same type of server installed in the liquid-cooling cabinet area to which the corresponding connection module belongs.

12. The structural layout method of the liquid-cooling cabinet according to claim 11, wherein after aligning and communicating the functional-plate interfaces on the functional plate with the corresponding functional interfaces of the server, the method comprising:
providing a detection switch at the functional-plate interface;
connecting all the detection switches corresponding to the same server in the connection module in series with an indicator light on the server, and electrifying them;
under the condition that the indicator light is on, determining that the functional-plate interface corresponding to the detection switch is in communication with the corresponding functional interface of the server;
under the condition that the indicator light is off, determining that the functional-plate interface corresponding to the detection switch not in communication with the corresponding functional interface of the server.

13. An electronic device, comprising a processor and a memory storing a computer program, wherein when the processor executes the computer program, the steps of a structural layout method of the liquid-cooling cabinet are realized, wherein the structural layout method of the liquid-cooling cabinet is for realizing the structure of the liquid-cooling cabinet, the liquid-cooling cabinet comprising: a cabinet frame and at least one connection module; wherein the connection module comprises a transverse plate and at least one functional plate, and the functional plate is perpendicularly connected with the transverse plate, and the transverse plate is horizontally connected with a side face of the cabinet frame; the functional plate is provided with a plurality of functional-plate interfaces; the transverse plate is provided with a plurality of transverse-plate connecting positions, and the functional plate is connected to any transverse-plate connecting position on the corresponding transverse plate, and the functional-plate interfaces are aligned and in communication with corresponding functional interfaces of a server in the cabinet frame; and/or the functional plate is perpendicularly provided with a plurality of functional-plate connecting positions, and the transverse plate is connected to any one of the functional-plate connecting positions, and the functional-plate interfaces are aligned and in communication with the corresponding functional interfaces of the server in the cabinet frame,
wherein the method comprising: determining the number of connection modules and the layout of functional plates in any one of the connection modules according to the type of the server; providing connection modules on any side face of the liquid-cooling cabinet according to the number and the layout; controlling the functional plate in the connection module to move horizontally and/or perpendicularly along the side face, and aligning and communicating the functional-plate interfaces on the functional plate with the corresponding functional interfaces of the server; wherein the server is the same type of server installed in the liquid-cooling cabinet area to which the corresponding connection module belongs.

14. (canceled)

15. The structural layout method of the liquid-cooling cabinet according to claim 11, wherein the transverse-plate connecting position is a first positioning hole, and the functional plate is connected to the corresponding first positioning hole.

16. The structural layout method of the liquid-cooling cabinet according to claim 11, wherein the transverse plate is provided with a slide rail, and the functional plate is suitable for moving along the slide rail, and the plurality of transverse-plate connecting positions is provided on the slide rail.

17. The structural layout method of the liquid-cooling cabinet according to claim 11, wherein the functional-plate connecting position is a second positioning hole, and the transverse plate is connected to the corresponding second positioning hole.

18. The structural layout method of the liquid-cooling cabinet according to claim 11, wherein the liquid-cooling cabinet further comprises: a fixing piece and a fixing bolt;
the fixing piece comprises a fixing-piece frame and a fixing-piece rear seat, and the fixing-piece rear seat is connected between the fixing-piece frame and the transverse plate;
the fixing-piece frame is provided with a through hole, the functional plate penetrates through the fixing-piece frame and is provided in the fixing-piece frame, and the fixing bolt penetrates through the through hole to press and connect the functional plate with the fixing-piece frame, and a pressing portion on the functional plate against the fixing-piece frame is the functional-plate connecting position.

19. The structural layout method of the liquid-cooling cabinet according to claim 11, wherein the functional plates with the same function in any two connection modules are interconnected, and the layout of functional plates in at least one connection module is different from the layout of functional plates in other connection modules.

20. The structural layout method of the liquid-cooling cabinet according to claim 11, wherein the functional plate comprises at least one of a liquid inlet main plate, a liquid outlet main plate, a power main plate or a communication main plate.
